(19) United States
(12) Patent Application Publication
(10) Pub. No.: US 2026/0076040 A1
(43) Pub. Date: Mar. 12, 2026

(54) DISPLAY DEVICE AND ELECTRONIC DEVICE

(71) Applicant: Samsung Display Co., Ltd., Yongin-si (KR)

(72) Inventor: Chun Gi YOU, Yongin-si (KR)

(21) Appl. No.: 19/216,947

(22) Filed: May 23, 2025

(30) Foreign Application Priority Data
Sep. 10, 2024 (KR) 10-2024-0123357

(51) Int. Cl. H10K 59/122; H10K 59/80

(52) U.S. Cl. CPC H10K 59/122; H10K 59/879

(57) ABSTRACT

A display device includes a substrate including a display area and a non-display area, a plurality of anode electrodes on the substrate, a pixel defining film on the plurality of anode electrodes, and defining a plurality of emission areas, a light emitting stack on the pixel defining film and the plurality of anode electrodes, a cathode electrode on the light emitting stack, a plurality of sub-optical layers on the cathode electrode, and a lens on the plurality of sub-optical layers, wherein a plurality of sub-pixels include a plurality of anode electrodes, a plurality of emission areas, a light emitting stack, a cathode electrode, a plurality of sub-optical layers, and a sub-optical layer shifted by a larger magnitude with an increase of its distance from a center of the display area, and wherein a deviation of a shift distance between neighboring sub-pixels is about 0.001 μm to about 0.009 μm.

### CROSS-REFERENCE TO RELATED APPLICATION

The present application claims priority to and the benefit of Korean Patent Application No. 10-2024-0123357, filed on Sep. 10, 2024, in the Korean Intellectual Property Office, the entire disclosure of which is incorporated herein by reference.

### BACKGROUND

### 1. Field

Aspects of embodiments of the present disclosure relate to a display device, an electronic device, and an optical device.

### 2. Description of the Related Art

A head mounted display (HMD) is an image display device that is worn on a user's head in the form of glasses or helmets to form a focus at a close distance in front of the user's eyes. The head mounted display may implement virtual reality (VR) or augmented reality (AR).

The head mounted display magnifies an image displayed on a small display device by using a plurality of lenses, and displays the magnified image. Therefore, the display device applied to the head mounted display needs to provide high-resolution images, for example, images with a resolution of 3000 PPI (Pixels Per Inch) or higher. To this end, an organic light emitting diode on silicon (OLEDoS), which is a high-resolution small organic light emitting display device, is used as the display device applied to the head mounted display. The OLEDOS is an image display device in which an organic light emitting diode (OLED) is disposed on a semiconductor wafer substrate on which a complementary metal oxide semiconductor (CMOS) is disposed.

The above information disclosed in this Background section is only for enhancement of understanding of the background of the invention and therefore it may contain information that does not form the prior art.

### SUMMARY

Aspects of some embodiments of the present disclosure are directed to a display device and an electronic device capable of improving image quality by minimizing or substantially reducing the number of stain defects.

According to some embodiments of the disclosure, there is provided a display device including: a substrate including a display area and a non-display area; a plurality of anode electrodes on the substrate; a pixel defining film on the plurality of anode electrodes, and defining a plurality of emission areas; a light emitting stack on the pixel defining film and the plurality of anode electrodes; a cathode electrode on the light emitting stack; a plurality of sub-optical layers on the cathode electrode; and a lens on the plurality of sub-optical layers, wherein a plurality of sub-pixels include a plurality of anode electrodes, a plurality of emission areas, a light emitting stack, a cathode electrode, a plurality of sub-optical layers, and a sub-optical layer shifted by a larger magnitude with an increase of its distance from a center of the display area, and wherein a deviation of a shift distance between neighboring sub-pixels is about 0.001 μm to about 0.009 μm.

In some embodiments, the deviation of the shift distance between the neighboring sub-pixels may be about 0.001 μm.

In some embodiments, the sub-optical layer may include a color filter; and a sub-lens on the color filter and overlapping with the color filter.

In some embodiments, the lens may overlap with a plurality of sub-lenses of the plurality of sub-pixels.

In some embodiments, the sub-lens may include a microlens.

In some embodiments, the shift distance may be a distance between a center of the emission area of the sub-pixel and a center of the sub-optical layer of the sub-pixel.

In some embodiments, the neighboring sub-pixels may be neighboring sub-pixels along an imaginary line connecting the center of the display area to an edge of the display area.

In some embodiments, a rate of change in a chief ray angle may vary gradually according to a distance from the center of the display area to the sub-pixel.

In some embodiments, the rate of change of the chief ray angle may gradually increase in proportion to the distance from the center of the display area to the sub-pixel.

In some embodiments, the lens may include a pancake lens.

According to some embodiments of the disclosure, there is provided an electronic device including: a display device including: a screen; a substrate including a display area and a non-display area; a plurality of anode electrodes on the substrate; a pixel defining film on the plurality of anode electrodes, and defining a plurality of emission areas; a light emitting stack on the pixel defining film and the plurality of anode electrodes; a cathode electrode on the light emitting stack; a plurality of sub-optical layers on the cathode electrode; and a lens on the plurality of sub-optical layers, wherein a plurality of sub-pixels include a plurality of anode electrodes, a plurality of emission areas, a light emitting stack, a cathode electrode, a plurality of sub-optical layers, and a sub-optical layer shifted by a larger magnitude with an increase of its distance from a center of the display area, and wherein a deviation of a shift distance between neighboring sub-pixels is about 0.001 μm to about 0.009 μm.

In some embodiments, the deviation of the shift distance between the neighboring sub-pixels may be about 0.001 μm.

In some embodiments, the sub-optical layer may include: a color filter; and a sub-lens on the color filter and overlapping with the color filter.

In some embodiments, the lens may overlap with a plurality of sub-lenses of the plurality of sub-pixels.

In some embodiments, the sub-lens may include a microlens.

In some embodiments, the shift distance may be a distance between a center of the emission area of the sub-pixel and a center of the sub-optical layer of the sub-pixel.

In some embodiments, the neighboring sub-pixels may be neighboring sub-pixels along an imaginary line connecting the center of the display area to an edge of the display area.

In some embodiments, a rate of change in a chief ray angle may vary gradually according to a distance from the center of the display area to the sub-pixel.

In some embodiments, the rate of change of the chief ray angle may gradually increase in proportion to the distance from the center of the display area to the sub-pixel.

In some embodiments, the lens may include a pancake lens.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exploded perspective view illustrating a display device according to some embodiments of the present disclosure;

FIG. 2 is a block diagram illustrating a display device according to some embodiments of the present disclosure;

FIG. 3 is an equivalent circuit diagram of a first sub-pixel according to some embodiments of the present disclosure;

FIG. 4 is a layout diagram illustrating a display panel according to some embodiments of the present disclosure;

FIG. 5 is a layout diagram showing the display area of FIG. 4 according to some embodiments of the present disclosure;

FIG. 6 is a layout diagram showing the display area of FIG. 4 according to some other embodiments of the present disclosure;

FIG. 7 is a cross-sectional view illustrating a display panel taken along line I1-I1′ of FIG. 5 according to some embodiments of the present disclosure;

FIG. 8 is a cross-sectional view of a display according to some embodiments of the present disclosure;

FIG. 9 is a diagram illustrating effects of a display device according to some embodiments of the present disclosure;

FIG. 10 is a perspective view illustrating a head mounted display according to some embodiments of the present disclosure;

FIG. 11 is an exploded perspective view illustrating the head mounted display of FIG. 10 according to some embodiments of the present disclosure; and

FIG. 12 is a perspective view illustrating a head mounted display according to some embodiments of the present disclosure.

FIG. 13 is a block diagram of an electronic device according to some embodiments of the present disclosure.

FIGS. 14, 15, and 16 are schematic diagrams of electronic devices according to some embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer 1 program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

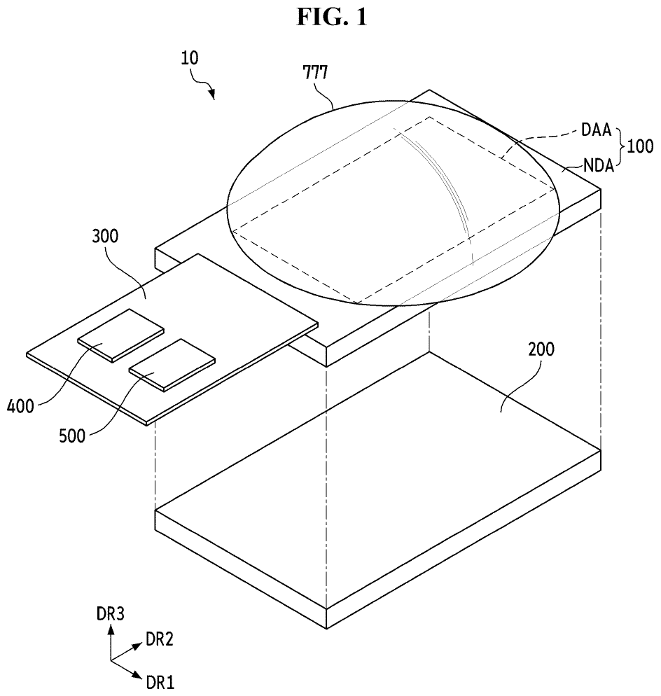

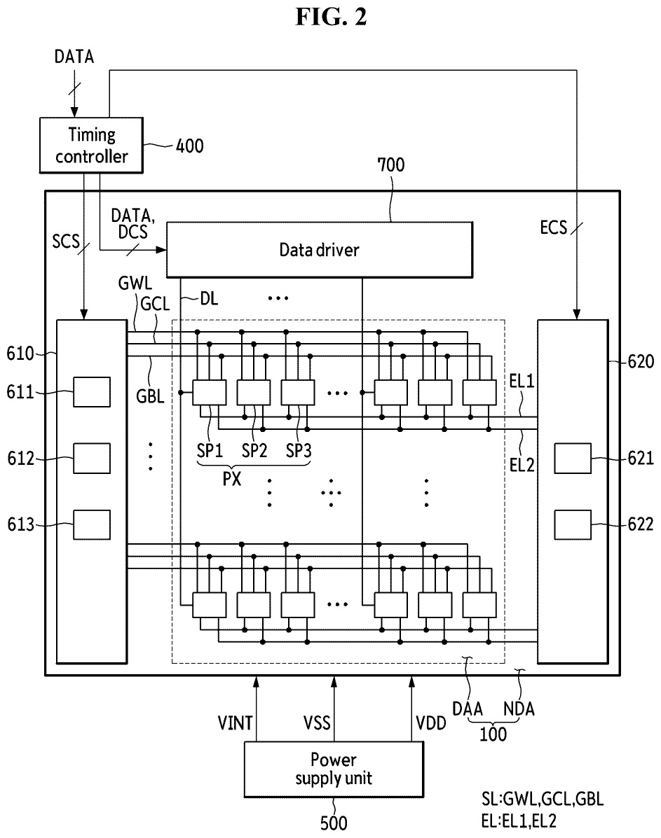

FIG. 1 is an exploded perspective view showing a display device according to some embodiments of the present disclosure. FIG. 2 is a block diagram illustrating a display device according to some embodiments of the present disclosure.

Referring to FIGS. 1 and 2, a display device 10 according to some embodiments is a device displaying a moving image or a still image. The display device 10 according to some embodiments may be applied to portable electronic devices, such as a mobile phone, a smartphone, a tablet personal computer, a mobile communication terminal, an electronic organizer, an electronic book, a portable multimedia player (PMP), a navigation system, an ultra mobile PC (UMPC), or the like. For example, the display device 10 according to some embodiments may be applied as a display unit of a television, a laptop, a monitor, a billboard, or an Internet-of-Things (IoT) terminal. For example, the display device 10 according to some embodiments may be applied to a smart watch, a watch phone, a head mounted display (HMD) for implementing virtual reality and augmented reality, and the like.

The display device 10 according to some embodiments may include a display panel 100, a heat dissipation layer 200, a circuit board 300, a timing control circuit 400, a power supply circuit 500, and a first lens 777.

The display panel 100 may have a planar shape (e.g., a quadrilateral shape or a similar shape). For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a curvature (e.g., a preset or predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

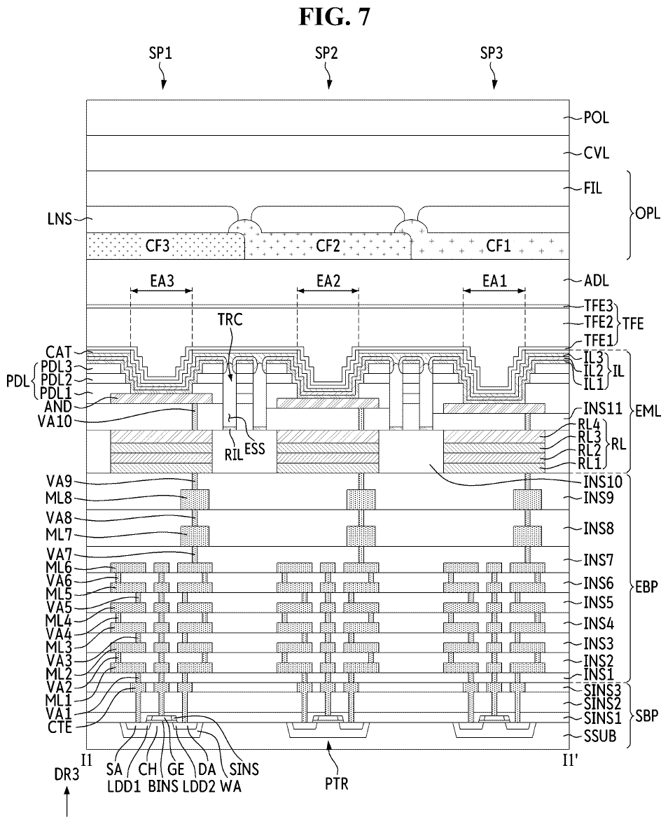

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image. For example, a substrate (e.g., a semiconductor substrate SSUB of FIG. 7) of the display panel 100 may include the display area DAA and the non-display area NDA.

The plurality of pixels PX may be disposed in the display area DAA. The plurality of pixels PX may be arranged in a matrix form (e.g., in a grid) in the first direction DR1 and the second direction DR2. The plurality of scan lines SL and the plurality of emission control lines EL may extend in the first direction DR1 and may be arranged in the second direction DR2. The plurality of data lines DL may extend in the second direction DR2 and may be arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines ECL1 and a plurality of second emission control lines ECL2.

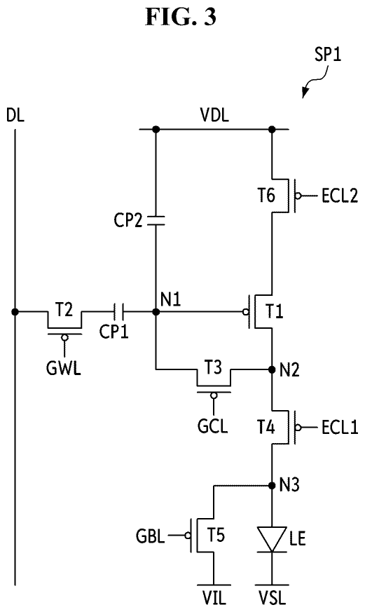

The plurality of pixels PX may include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see, e.g., FIG. 7). For example, the plurality of pixel transistors of the data driver 700 may be formed of complementary metal oxide semiconductor (CMOS), but the present disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be disposed in the non-display area NDA.

The scan driver 610 may include a plurality of scan transistors, and the emission driver 620 includes a plurality of light emitting transistors. The plurality of scan transistors and the plurality of light emitting transistors may be formed on the semiconductor substrate SSUB (see, e.g., FIG. 7) through a semiconductor process. For example, the plurality of scan transistors and the plurality of light emitting transistors may be formed of CMOS, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed on the semiconductor substrate SSUB (see, e.g., FIG. 7) through a semiconductor process. For example, the plurality of data transistors may be formed of CMOS, but the present disclosure is not limited thereto.

The data driver 700 may receive digital video data DATA and a data timing control signal DCS from the timing control circuit 400. The data driver 700 may convert the digital video data DATA into analog data voltages according to (e.g., based on) the data timing control signal DCS and may output the analog data voltages to the data lines DL. For example, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap with the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

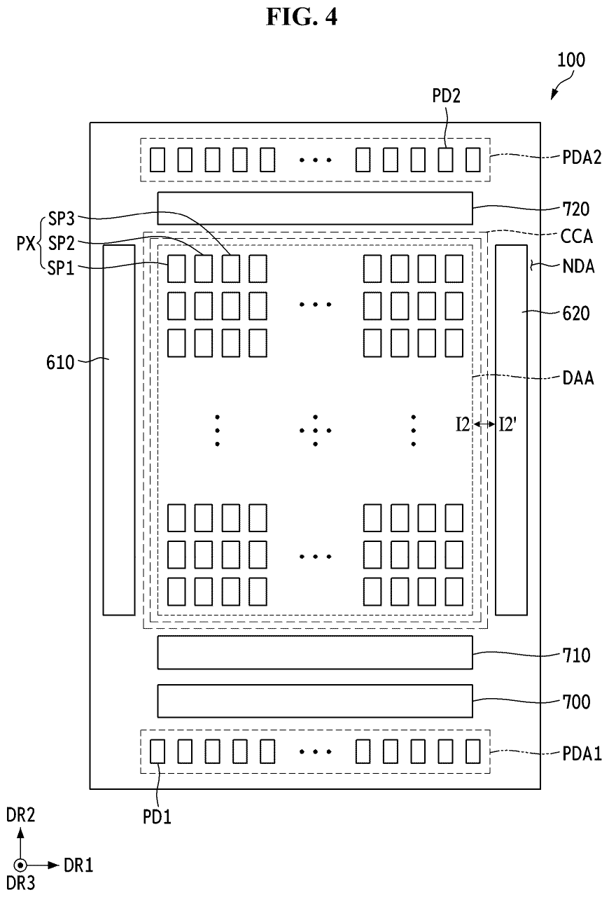

The circuit board 300 may be electrically connected to a plurality of first pads PD1 (see, e.g., FIG. 4) of a first pad portion PDA1 (see, e.g., FIG. 4) of the display panel 100 by using a conductive adhesive member, such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. For example, one end of the circuit board 300 may be disposed on the rear surface of the display panel 100 and/or the rear surface of the heat dissipation layer 200. The other end of the circuit board 300 may be connected to the plurality of first pads PD1 (see, e.g., FIG. 4) of the first pad portion PDA1 (see, e.g., FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. For example, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

For example, each of the timing control circuit 400 and the power supply circuit 500 may be disposed in the non-display area NDA of the display panel 100, similarly to the scan driver 610, the emission driver 620, and the data driver 700. For example, the timing control circuit 400 may include a plurality of timing transistors, and each power supply circuit 500 may include a plurality of power transistors. The plurality of timing transistors and the plurality of power transistors may be formed on the semiconductor substrate SSUB (see, e.g., FIG. 7) through a semiconductor process. For example, the plurality of timing transistors and the plurality of power transistors may be formed of CMOS, but the present disclosure is not limited thereto. Each of the timing control circuit 400 and the power supply circuit 500 may be disposed between the data driver 700 and the first pad portion PDA1 (see, e.g., FIG. 4).

The first lens 777 may be disposed on the display panel 100. For example, the first lens 777 may be disposed on the display panel 100 so as to overlap with the display area DAA of the display panel 100. The first lens 777 may overlap with the 1 entire display area DAA. For example, in a plan view, the first lens 777 may surround the edge of the display area DAA. The first lens 777 may have a hemispherical shape. The first lens may include, for example, a pancake lens.

FIG. 3 is an equivalent circuit diagram of a first sub-pixel according to some embodiments of the present disclosure.

Referring to FIG. 3, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 may include a plurality of transistors T1 to T6, a light emitting element LE, a first capacitor CP1, and a second capacitor CP2.

The light emitting element LE emits light in response to a driving current flowing through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the present disclosure is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current (e.g., a driving current) flowing between the source electrode and the drain electrode thereof according to a voltage applied to the gate electrode thereof.

A second transistor T2 may be disposed between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be disposed between a first node N1 and a second node N2. The third transistor T3 may be turned on by the write control signal of the write control line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 may be turned on by the first emission control signal of the first emission control line ECL1 to connect the second node N2 to the third node N3. Accordingly, the driving current of the first transistor T1 may be supplied to the light emitting element LE.

A fifth transistor T5 may be disposed between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be disposed between the source electrode of the first transistor T1 and the second driving voltage line VDL. The sixth transistor T6 may be turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 may be disposed between the first node N1 and the drain electrode of the second transistor T2. The second capacitor CP2 may be disposed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. For example, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating a display panel according to some embodiments of the present disclosure.

Referring to FIG. 4, the display area DAA of the display panel 100 according to some embodiments includes the plurality of pixels PX arranged in a matrix form. The non-display area NDA of the display panel 100 according to some embodiments includes the scan driver 610, the emission driver 620, the data driver 700, a first distribution circuit 710, a second distribution circuit 720, the first pad portion PDA1, and a second pad portion PDA2.

The scan driver 610 may be disposed on a first side of the display area DAA, and the emission driver 620 may be disposed on a second side of the display area DAA. For example, the scan driver 610 may be disposed on one side of the display area DAA in the first direction DR1, and the emission driver 620 may be disposed on another side of the display area DAA in the first direction DR1. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on a third side of the display area DAA. For example, the first pad portion PDA1 may be disposed on one side of the display area DAA in the second direction DR2. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The second pad portion PDA2 may be disposed on a fourth side of the display area DAA. For example, the second pad portion PDA2 may be disposed on another side of the display area DAA opposite the side having the first pad portion PDA1 in the second direction DR2. The second pad portion PDA2 may be disposed outside the second distribution circuit 720 in the second direction DR2. In other words, the second pad portion PDA2 may be disposed farther from the display area DAA in the second direction than the second distribution circuit 720 is.

The first distribution circuit 710 may distribute data voltages applied through the first pad portion PDA1 to the plurality of data lines DL. For example, the first distribution circuit 710 may distribute the data voltages applied through one first pad PD1 of the first pad portion PDA1 to the plurality of data lines DL (see, e.g., FIG. 2), and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2.

The second distribution circuit 720 may distribute signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on another side of the display area DAA opposite the side having the first distribution circuit 710 in the second direction DR2.

A cathode connection portion CCA may be a region in which a second electrode CAT (see, e.g., FIG. 7) of a display element layer EML (see, e.g., FIG. 7) is connected to the first driving voltage line VSL of the non-display area NDA. The cathode connection portion CCA may be disposed outside at least one side of the display area DAA. For example, the cathode connection portion CCA may be disposed outside at least on one side among the left side, the right side, the upper side, and the lower side of the display area DAA. For example, the cathode connection portion CCA may be disposed to surround the display area DAA as shown in FIG. 4 in order to substantially reduce or minimize a deviation in the first driving voltage VSS due to a voltage drop (e.g., IR drop) or voltage rise (e.g., IR rising) of the second electrode CAT in the display area DAA.

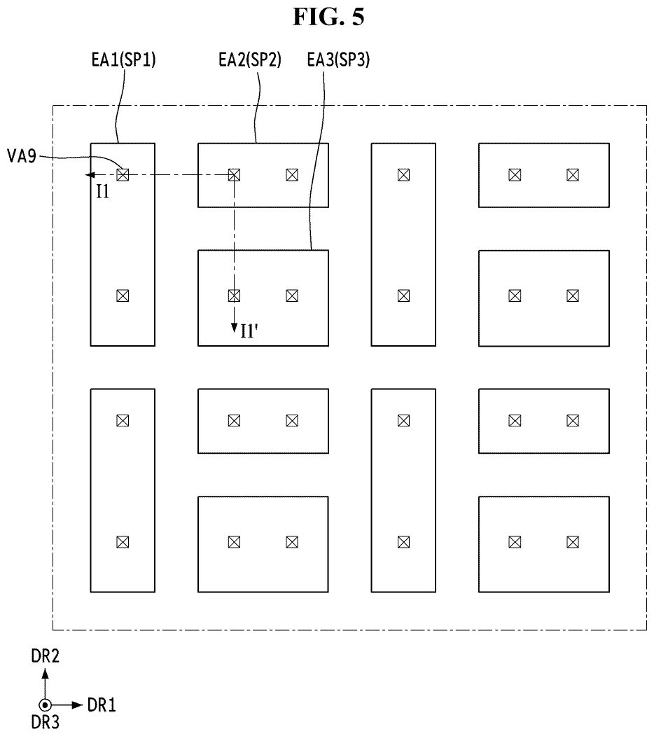

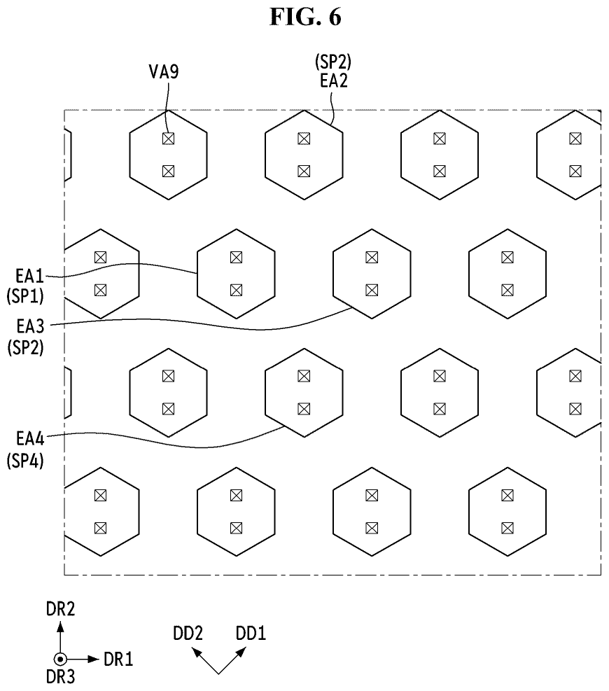

FIG. 5 is a layout diagram showing the display area of FIG. 4 according to some embodiments of the present disclosure. FIG. 6 is a layout diagram showing the display area of FIG. 4 according to some other embodiments of the present disclosure.

Referring to FIGS. 5 and 6, each of the pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

The first emission area EA1, the second emission area EA2, and the third emission area EA3 may have, in a plan view, a quadrilateral or hexagonal shape as shown in FIGS. 5 and 6, but the present disclosure is not limited thereto. The first emission area EA1, the second emission area EA2, and the third emission area EA3 may have a polygonal shape other than a quadrangle or hexagon, a circular shape, an elliptical shape, or an atypical shape, in a plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different from each other.

For example, as shown in FIG. 6, the emission areas EA1, EA2, EA3, and EA4 may have a hexagonal shape in a plan view. For example, the first emission area EA1 and the third emission area EA3 may be adjacent in the first direction DR1, and the second emission area EA2 and the fourth emission area EA4 may be adjacent in the second direction DR2. Additionally, the first emission area EA1 and the second 1 emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2. The second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to about 460 nm, the green wavelength band may be a wavelength band of light whose main peak wavelength is in the range of approximately 480 nm to about 560 nm, and the red wavelength band may be a wavelength band of light whose main peak wavelength is in the range of approximately 600 nm to about 750 nm.

Each of the plurality of pixels PX may include three emission areas EA1, EA2, and EA3 as shown in FIG. 5, or may include four emission areas EA1, EA2, EA3, and EA4 as shown in FIG. 6. For example, the fourth emission area EA4 may emit the same second light as the second emission area EA2, but the present disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombus shape, or a hexagonal structure in which the emission areas each having a hexagonal shape are arranged as shown in FIG. 6.

FIG. 7 is a cross-sectional view illustrating a display panel taken along line I1-I1′ of FIG. 5 according to some embodiments of the present disclosure.

Referring to FIG. 7, the display panel 100 may include a semiconductor backplane SBP, a light emitting element backplane EBP, the display element layer EML, an encapsulation layer TFE, an optical layer OPL, a cover layer CVL, and a polarizing plate POL.

The semiconductor backplane SBP may include the semiconductor substrate SSUB including a plurality of pixel transistors PTR, a plurality of semiconductor insulating films SINS1, SINS2, and SINS3 covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. For example, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap with the well region WA in the third direction DR3, which is the thickness direction of the semiconductor substrate SSUB. The channel region CH may overlap with the gate electrode GE in the third direction DR3. The source region SA may be disposed on one side of the gate electrode GE, and the drain region DA may be disposed on the other side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, which may result in an increase of the length of the channel region CH of each of the pixel transistors PTR.

A first semiconductor insulating film SINS1 may be disposed on the semiconductor substrate SSUB. A second semiconductor insulating film SINS2 may be disposed on the first semiconductor insulating film SINS1.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed of silicon carbonitride (SiCN) or a silicon oxide (SiOx)-based inorganic film, but the present disclosure is not limited thereto.

The semiconductor substrate SSUB may be replaced with a glass substrate or a polymer resin substrate, such as polyimide. For example, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP may include a plurality of conductive layers ML1 to ML8, a plurality of vias VA1 to VA9, and a plurality of insulating films INS1 to INS9. In addition, the light emitting element backplane EBP includes a plurality of insulating films INS1 to INS9 disposed between the first to eighth conductive layers ML1 to ML8.

The first to eighth insulating films INS1 to INS8 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 3.

For example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating films INS1 to INS8 may be formed of a silicon oxide (SiOx)-based inorganic film, but the present disclosure is not limited thereto.

A ninth insulating film INS9 may be disposed on the eighth insulating film INS8 and the eighth conductive layer ML8. The ninth insulating film INS9 may be formed of a silicon oxide (SiOx)-based inorganic film, but the present disclosure is not limited thereto.

Each of a plurality of ninth vias VA9 may penetrate the ninth insulating film INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be disposed on the light emitting element backplane EBP. The display element layer EML may include tenth and eleventh insulating films INS10 and INS11, a reflective electrode RL, the first electrodes AND, a light emitting stack IL, the second electrode CAT, a pixel defining film PDL, and a plurality of trenches TRC.

The reflective electrode RL may be disposed on the ninth insulating film INS9. The reflective electrode RL may include at least one reflective electrode RL1, RL2, RL3, and RL4. For example, the reflective electrode RL may include the first to fourth reflective electrodes RL1, RL2, RL3, and RL4 as shown in FIG. 7.

The first reflective electrodes RL1 may be disposed on the ninth interlayer insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Because the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TIN), the second reflective electrodes RL2 may include aluminum (Al), the third reflective electrodes RL3 may include titanium nitride (TiN), and the fourth reflective electrodes RL4 may include titanium (Ti).

The tenth interlayer insulating film INS10 may be disposed on the ninth interlayer insulating film INS9. The tenth interlayer insulating film INS10 may be disposed between the reflective electrodes RL adjacent to each other. The tenth interlayer insulating film INS10 may be a film for flattening a stepped portion caused by the reflective electrodes RL. The eleventh interlayer insulating film INS11 may be disposed on the tenth interlayer insulating film INS10 and the reflective electrode RL.

The tenth interlayer insulating film INS10 and the eleventh interlayer insulating film INS11 may be formed of a silicon oxide (SiOx)-based inorganic film, but the present disclosure is not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, as shown in FIG. 7, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. For example, the distance between the first electrode AND and the reflective electrode RL in the first sub-pixel SP1 may be greater than the distance between the first electrode AND and the reflective electrode RL in the second sub-pixel SP2. In addition, the distance between the first electrode AND and the reflective electrode RL in the second sub-pixel SP2 may be greater than the distance between the first electrode AND and the reflective electrode RL in the third sub-pixel SP3.

Each of the tenth vias VA10 may penetrate the eleventh interlayer insulating film INS11 and be connected to the exposed eighth metal layer ML8. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be disposed on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge (e.g., a side surface) of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film. For example, the first pixel defining film PDL1 and the third pixel defining film PDL3 may be formed of a silicon nitride (SiNx)-based inorganic film, whereas the second pixel defining film PDL2 may be formed of a silicon oxide (SiOx)-based inorganic film. The first pixel defining film PDL1, the second pixel defining film PDL2, and the third pixel defining film PDL3 may each have a thickness of about 500 Å.

In order to prevent or reduce the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree (e.g., amount) of thin film coated on an inclined portion (e.g. a vertical portion) to the degree (e.g., amount) of thin film coated on a flat portion (e.g., a 1 horizontal portion). The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be disposed between the neighboring sub-pixels SP1, SP2, and SP3. Although FIG. 7 illustrates that two trenches TRC are disposed between the neighboring sub-pixels SP1, SP2, and SP3, the present disclosure is not limited thereto.

The light emitting stack IL may include a plurality of stack layers IL1, IL2, and IL3. FIG. 7 illustrates that the light emitting stack IL has a three-tandem structure including a first stack layer IL1, a second stack layer IL2, and a third stack layer IL3, but the present disclosure is not limited thereto. For example, the light emitting stack IL may have a two-tandem structure including two stack layers.

In the three-tandem structure, the light emitting stack IL may have a tandem structure including a plurality of intermediate layers IL1, IL2, and IL3 that emit different lights. For example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and a residual film RIL disposed on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the residual film RIL and the second stack layer IL2 in the trench TRC. The third stack layer IL3 may be disposed on the second stack layer IL2. The third stack layer IL3 is not cut off by the trench TRC and may be disposed to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In addition, in the two-tandem structure, each of the plurality of trenches TRC may be a structure for cutting off the charge generation layer and the lower stack layer disposed between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, another structure may exist instead of the trench TRC. For example, instead of the trench TRC, a reverse-tapered partition wall may be disposed on the pixel defining film PDL.

In addition, FIG. 7 illustrates that the light emitting stack IL that emits light is disposed in the first emission area EA1, the second emission area EA2, and the third emission area EA3, but the present disclosure is not limited thereto. For example, instead of the light emitting stack IL, the first light emitting layer may be disposed in the first emission area EA1, and may be omitted from the second emission area EA2 and the third emission area EA3. Furthermore, the second light emitting layer may be disposed in the second emission area EA2 and may be omitted from the first emission area EA1 and the third emission area EA3. Furthermore, the third light emitting layer may be disposed in the third emission area EA3 and may be omitted from the first emission area EA1 and the second emission area EA2. For example, first to third color filters CF1, CF2, and CF3 of the optical layer OPL may be omitted.

The second electrode CAT may be disposed on the light emitting stack IL. The second electrode CAT may be disposed on the third stack layer IL3 in each of the plurality of trenches TRC. The second electrode CAT may be formed of a transparent conductive material (e.g., a transparent conductive oxide or TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE3 to prevent oxygen or moisture from permeating into the display element layer EML or substantially reduce the likelihood thereof. The first encapsulation inorganic film TFE1 may be disposed on the second electrode CAT, and the second encapsulation inorganic film TFE3 may be disposed on the first encapsulation inorganic film TFE1. The first encapsulation inorganic film TFE1 and the second encapsulation inorganic film TFE3 may be formed of multiple layers in which one or more inorganic films of silicon nitride (SiNx), silicon oxynitride (SiON), silicon oxide (SiOx), titanium oxide (TiOx), and aluminum oxide (AIOx) layers are alternately stacked.

In addition, the encapsulation layer TFE may include at least one encapsulation organic film TFE2 to protect the display element layer EML from foreign substances such as dust. The at least one encapsulation organic film TFE2 of the encapsulation layer TFE may be disposed between the first encapsulation inorganic film TFE1 and the second encapsulation inorganic film TFE3. The at least one encapsulation organic film TFE2 of the encapsulation layer TFE may be a monomer. For example, at least one organic film of the encapsulating layer TFE may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL may include a plurality of color filters CF1, CF2, and CF3, a plurality of second lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap with the first emission area EA1 of the first sub-pixel SP1. The first color filter CF1 may transmit light of the first color (e.g., light of a blue wavelength band). The blue wavelength band may be about 370 nm to about 460 nm. Thus, the first color filter CF1 may transmit light of the first color among light emitted from the first emission area EA1.

The second color filter CF2 may overlap with the second emission area EA2 of the second sub-pixel SP2. The second color filter CF2 may transmit light of the second color (e.g., light of a green wavelength band). The green wavelength band may be about 480 nm to about 560 nm. Thus, the second color filter CF2 may transmit light of the second color among light emitted from the second emission area EA2.

The third color filter CF3 may overlap with the third emission area EA3 of the third sub-pixel SP3. The third color filter CF3 may transmit light of the third color (e.g., light of a red wavelength band). The red wavelength band may be about 600 nm to about 750 nm. Thus, the third color filter CF3 may transmit light of the third color among light emitted from the third emission area EA3.

The plurality of second lenses LNS may be disposed on the first color filter CF1, the second color filter CF2, and the third color filter CF3, respectively. Each of the plurality of second lenses LNS may be a structure for increasing the proportion of light directed to the front of the display device 10. Each of the plurality of second lenses LNS may have a cross-sectional shape that is convex in an upward direction. Each of the plurality of second lenses LNS may include a microlens.

The filling layer FIL may be disposed on the plurality of second lenses LNS. The filling layer FIL may have a refractive index (e.g., a preset or predetermined refractive index) such that light travels in the third direction DR3 at an interface between the filling layer FIL and the plurality of second lenses LNS. Further, the filling layer FIL may be a planarization layer. The filling layer FIL may be an organic film, such as acrylic resin, epoxy resin, phenolic resin, polyamide resin, or polyimide resin.

The cover layer CVL may be disposed on the filling layer FIL. The cover layer CVL may be a glass substrate or a polymer resin. When the cover layer CVL is a glass substrate, it may be attached onto the filling layer FIL. For example, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be disposed on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a N/4 plate (quarter-wave plate), but the present disclosure is not limited thereto. However, when visibility degradation caused by reflection of external light is sufficiently overcome by the first to third color filters CF1, CF2, and CF3, the polarizing plate POL may be omitted.

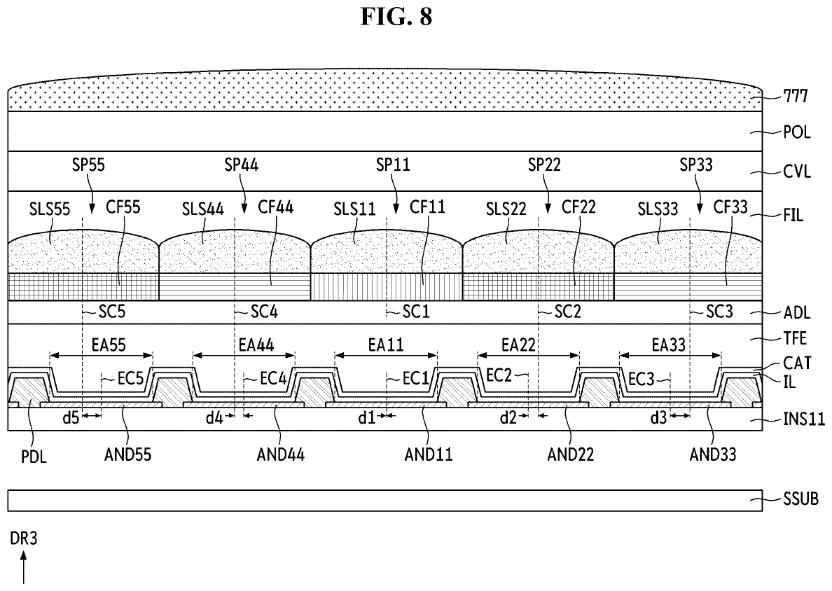

FIG. 8 is a cross-sectional view of a display device according to some embodiments of the present disclosure.

The display device of FIG. 8 is different from the display device of FIG. 7 described above at least in the arrangement position of a color filter and a second lens with respect to an emission area in a sub-pixel, and this difference will be described below.

As shown in FIG. 8, the first lens 777 may be disposed on the polarizing plate POL so as to overlap with a plurality of second lenses SLS11, SLS22, SLS33, SLS44, and SLS55.

Five sub-pixels SP11, SP22, SP33, SP44, and SP55 are illustrated in FIG. 8. For example, the first sub-pixel SP11, the second sub-pixel SP22, the third sub-pixel SP33, the fourth sub-pixel SP44, and the fifth sub-pixel SP55 are illustrated in FIG. 8. Each of the sub-pixels SP11, SP22, SP33, SP44, and SP55 may include a first electrode (hereinafter, referred to as anode electrode), the light emitting stack IL, the second electrode CAT (hereinafter, referred to as cathode electrode CAT), a color filter, and a second lens (hereinafter, referred to as sub-lens).

The first sub-pixel SP11 may include a first emission area EA11, a first anode electrode AND11, the light emitting stack IL, the cathode electrode CAT, a first color filter CF11, and a first sub-lens SLS11. Here, the light emitting stack IL of the first sub-pixel SP11 may mean (e.g., refer to) the light emitting stack IL between the first anode electrode AND11 and the cathode electrode CAT. The first color filter CF11 and the first sub-lens SLS11 may overlap with each other.

The second sub-pixel SP22 may include a second emission area EA22, a second anode electrode AND22, the light emitting stack IL, the cathode electrode CAT, a second color filter CF22, and a second sub-lens SLS22. Here, the light emitting stack IL of the second sub-pixel SP22 may mean the light emitting stack IL between the second anode electrode AND22 and the cathode electrode CAT. The second color filter CF22 and the second sub-lens SLS22 may overlap with each other.

The third sub-pixel SP33 may include a third emission area EA33, a third anode electrode AND33, the light emitting stack IL, the cathode electrode CAT, a third color filter CF33, and a third sub-lens SLS33. Here, the light emitting stack IL of the third sub-pixel SP33 may mean the light emitting stack IL between the third anode electrode AND33 and the cathode electrode CAT. The third color filter CF33 and the third sub-lens SLS33 may overlap with each other.

The fourth sub-pixel SP44 may include a fourth emission area EA44, a fourth anode electrode AND44, the light emitting stack IL, the cathode electrode CAT, a fourth color filter CF44, and a fourth sub-lens SLS44. Here, the light emitting stack IL of the fourth sub-pixel SP44 may mean the light emitting stack IL between the fourth anode electrode AND44 and the cathode electrode CAT. The fourth color filter CF44 and the fourth sub-lens SLS44 may overlap with each other.

The fifth sub-pixel SP55 may include a fifth emission area EA55, a fifth anode electrode AND55, the light emitting stack IL, the cathode electrode CAT, a fifth color filter CF55, and a fifth sub-lens SLS55. Here, the light emitting stack IL of the fifth sub-pixel SP55 may mean the light emitting stack IL between the fifth anode electrode AND55 and the cathode electrode CAT. The fifth color filter CF55 and the fifth sub-lens SLS55 may overlap with each other.

The first sub-pixel SP11 may be disposed at the center of the display panel 100 (or the display area DAA of the display panel 100, or the first lens 777). For example, the first sub-pixel SP11 may overlap with the center of the first lens 777. For example, the center of the first anode electrode AND11, the center of the first emission area EA11, the center of the first color filter CF11, and the center of the first lens 777 may overlap with each other. Here, the first sub-pixel SP11 may be defined as a central sub-pixel.

The second to fifth sub-pixels SP22 to SP55 may be sequentially disposed on one side or the other side of the first sub-pixel SP11 with respect to the first sub-pixel SP11. For example, the second sub-pixel SP22 and the third sub-pixel SP33 may be sequentially disposed on one side of the first sub-pixel SP11, and the fourth sub-pixel SP44 and the fifth sub-pixel SP55 may be sequentially disposed on another side of the first sub-pixel SP11. Here, the second to fifth sub-pixels SP22 to SP55 may be defined as peripheral sub-pixels.

When a color filter and a sub-lens included in one sub-pixel are defined as a sub-optical layer of the one sub-pixel, a center SC1 of a sub-optical layer of the central sub-pixel (e.g., the first sub-pixel SP11) disposed at the center of the display panel 100 (or at the center of the display area DAA, or at the center of the first lens 777) may overlap with a center EC1 of the first emission area EA11 of the central sub-pixel (e.g., the first sub-pixel SP11).

For example, the center of a sub-optical layer of a peripheral sub-pixel may not overlap with the center of an emission area of that peripheral sub-pixel. To this end, the sub-optical layer of the peripheral sub-pixel may be shifted by a distance (e.g., a preset or a predetermined distance) toward the edge of the display panel 100 (or the display area DAA of the display panel 100 of FIG. 1, or the first lens 777) with respect to the center of the emission area of the peripheral sub-pixel. For example, the sub-optical layer (or a center SC2 of the sub-optical layer) of the second sub-pixel SP22 may be shifted by a distance (e.g., a preset or a predetermined distance) toward the edge of the display panel 100 (or the display area DAA of the display panel 100, or the first lens 777) with respect to a center EC2 of the second emission area EA22; the sub-optical layer (or a center SC3 of the sub-optical layer) of the third sub-pixel SP33 may be shifted by a distance (e.g., a preset or a predetermined distance) toward the edge of the display panel 100 (or the display area DAA of the display panel 100, or the first lens 777) with respect to a center EC3 of the third emission area EA33; the sub-optical layer (or a center SC4 of the sub-optical layer) of the fourth sub-pixel SP44 may be shifted by a distance (e.g., a preset or a predetermined distance) toward the edge of the display panel 100 (or the display area DAA of the display panel 100, or the first lens 777) with respect to a center EC4 of the fourth emission area EA44; and the sub-optical layer (or a center SC5 of the sub-optical layer) of the fifth sub-pixel SP55 may be shifted by a distance (e.g., a preset or a predetermined distance) toward the edge of the display panel 100 (or the display area DAA of the display panel 100, or the first lens 777) with respect to a center EC5 of the fifth emission area EA55.

The sub-optical layer of the peripheral sub-pixel may be shifted by a larger magnitude with an increase of its distance from the central sub-pixel. For example, between the second sub-pixel SP22 and the third sub-pixel SP33 sequentially disposed on one side of the first sub-pixel SP11, the third sub-pixel SP33 disposed relatively farther from the first sub-pixel SP11 may include a sub-optical layer shifted by a larger magnitude than the sub-optical layer of the second sub-pixel SP22. As another example, between the fourth sub-pixel SP44 and the fifth sub-pixel SP55 sequentially disposed on the other side of the first sub-pixel SP11, the fifth sub-pixel SP55 disposed relatively farther from the first sub-pixel SP11 may include a sub-optical layer shifted by a larger magnitude than that the sub-optical layer of the fourth sub-pixel SP44.

In other words, the sub-pixels SP11 to SP55 may include the sub-optical layers shifted by larger magnitudes as they are located farther from the center of the display panel 100 (or the display area DAA of the display panel 100, or the first lens 777). For example, when the distance between the center of the emission area of the sub-pixel and the center of the sub-optical layer of that sub-pixel is defined as a shift distance of that sub-pixel (or a shift distance of the sub-optical layer of that sub-pixel), a shift distance d1 of the first sub-pixel SP11 may be substantially zero; a shift distance d3 of the third sub-pixel SP33 may be greater than a shift distance d2 of the second sub-pixel SP22; and a shift distance d5 of the fifth sub-pixel SP55 may be greater than a shift distance d4 of the fourth sub-pixel SP44.

As the sub-pixels SP11 to SP55 include the sub-optical layers shifted by the larger magnitudes as they are located farther from the center of the display panel 100 (or the display area DAA of the display panel 100, or the first lens 777) as described above, light at the edge of the first lens 777 may be emitted to the outside while satisfying a chief ray angle (CRA).

According to some embodiments, a deviation of the shift distance between the neighboring sub-pixels along an imaginary line connecting the center of the display panel 100 (or the display area DAA of the display panel 100, or the first lens 777) to the edge of the display panel 100 (or the display area DAA of the display panel 100, or the first lens 777) may be in the range of about 0.001 μm to about 0.009 μm. For example, the deviation of the shift distance described above may be about 0.001 μm. For example, a difference between the shift distance d2 of the second sub-pixel SP22 and the shift distance d3 of the third sub-pixel SP33 may be about 0.001 μm. As stated above, because the shift deviation between the neighboring sub-pixels is relatively small, a gradual rate of change in the chief ray angle according to the distance from the center of the display panel 100 (or the display area DAA of the display panel 100, or the first lens 777) to the sub-pixel may be achieved. For example, the rate of change in the chief ray angle may gradually increase in proportion to the distance from the center of the display panel 100 (or the display area DAA of the display panel 100, or the first lens 777) to the sub-pixel. Therefore, occurrence of stains (e.g., barcode stains) at the edge of the display panel 100 may be further minimized or substantially reduced, so that the image quality of the display device 10 may be improved.

For example, the constituent components between the semiconductor substrate SSUB and the eleventh insulating film INS11 of FIG. 7 may also be disposed between the substrate SSUB (e.g., the semiconductor substrate SSUB) and the eleventh insulating film INS11 of FIG. 8.

Also, the pixel defining film PDL of FIG. 8 may include the first pixel defining film PDL1, the second pixel defining film PDL2, and the third pixel defining film PDL3 of FIG. 7.

In addition, the light emitting stack IL of FIG. 8 may include the first stack layer IL1, the second stack layer IL2, and the third stack layer IL3 of FIG. 7.

Moreover, the encapsulation layer TFE of FIG. 8 may include the first encapsulation inorganic film TFE1, the encapsulation organic film TFE2, and the second encapsulation inorganic film TFE3 of FIG. 7.

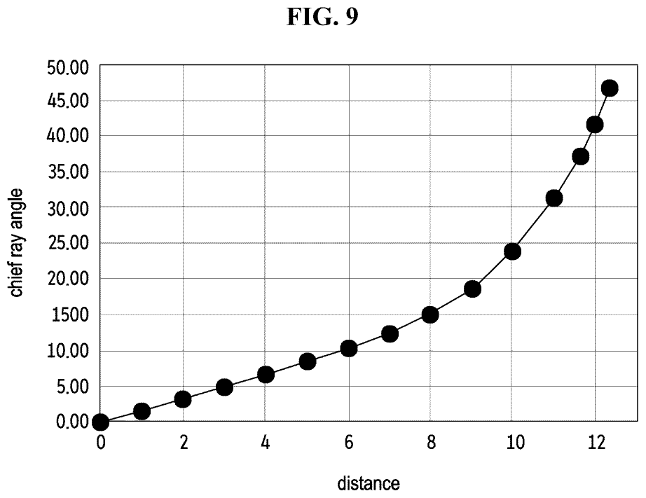

FIG. 9 is a diagram illustrating effects of a display device according to some embodiments of the present disclosure.

In FIG. 9, the X-axis represents a distance, and the −Y axis represents a chief ray angle. Here, the X-axis may mean a distance from the center of a display panel to a sub-pixel. As shown in FIG. 9, as the distance from the center of the display panel to the sub-pixel increases, the chief ray angle may exponentially change. For example, a gradual rate of change in the chief ray angle according to the distance from the center of the display panel may be achieved. Accordingly, the image quality of the display device may be improved.

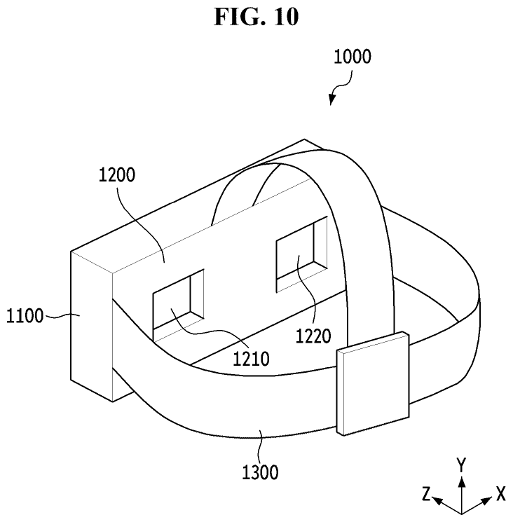

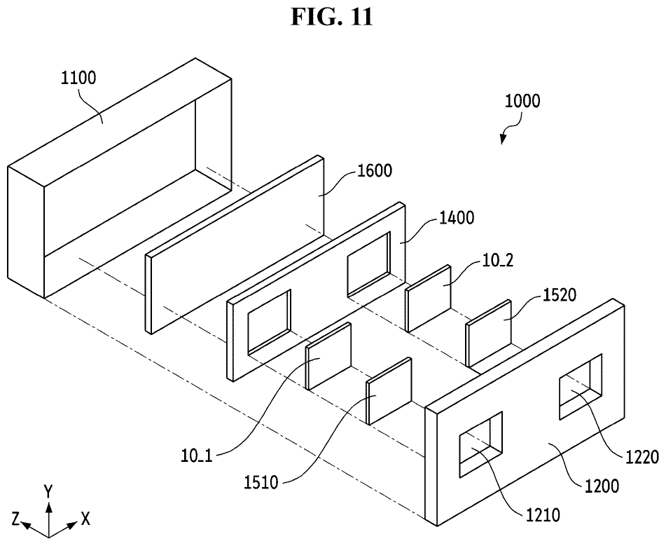

FIG. 10 is a perspective view illustrating a head mounted display according to some embodiments of the present disclosure. FIG. 11 is an exploded perspective view illustrating the head mounted display of FIG. 10 according to some embodiments of the present disclosure.

Referring to FIGS. 10 and 11, a head mounted display 1000 according to some embodiments may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 10_2 may provide an image to the user's right eye. Because each of the first display device 10_1 and the second display device 10_2 is substantially the same as the display device 10 described in conjunction with FIGS. 1 to 8, the description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix 1 the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA (see, e.g., FIG. 2), and transmit the digital video data DATA to the first display device 10_1 and the second display device 10_2 through the connector.

The control circuit board 1600 may transmit the digital video data DATA corresponding to a left-eye image suitable (e.g., adjusted) for the user's left eye to the first display device 10_1, and may transmit the digital video data DATA corresponding to a right-eye image suitable (e.g., adjusted) for the user's right eye to the second display device 10_2. For example, the control circuit board 1600 may transmit the same digital video data DATA to the first display device 10_1 and the second display device 10_2.

The display device housing 1100 may serve to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 10 and 11 illustrate that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

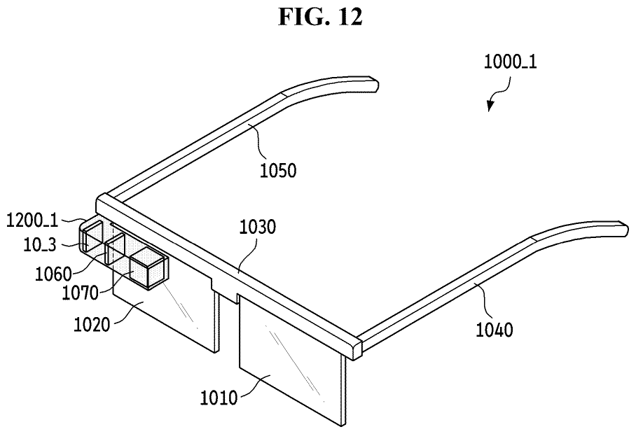

The head mounted band 1300 may serve to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with an eyeglass frame as shown in FIG. 12 instead of the head mounted band 1300.

FIG. 12 is a perspective view illustrating a head mounted display according to some embodiments of the present disclosure.

Referring to FIG. 12, a head mounted display 1000_1 according to some embodiments may be an eyeglasses-type display device in which a display device housing 1200_1 is implemented in a lightweight and compact manner. The head mounted display 1000_1 according to some embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on (e.g., displayed by) the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 12 illustrates that the display device housing 1200_1 is disposed at the right end of the support frame 1030, but the present disclosure is not limited thereto. For example, the display device housing 1200_1 may be disposed at the left end of the support frame 1030, and for example, the image of the display device 10_3 may be provided to the user's left eye. For example, the display device housing 1200_1 may be disposed at both the left and right ends of the support frame 1030, and in this case, the user may view the image displayed on the display device 10_3 through both the left and right eyes.

The display device according to some embodiments can be applied to various suitable electronic devices. The electronic device according to some embodiments includes the display device described above and may further include modules or devices having additional functions in addition to the display device.

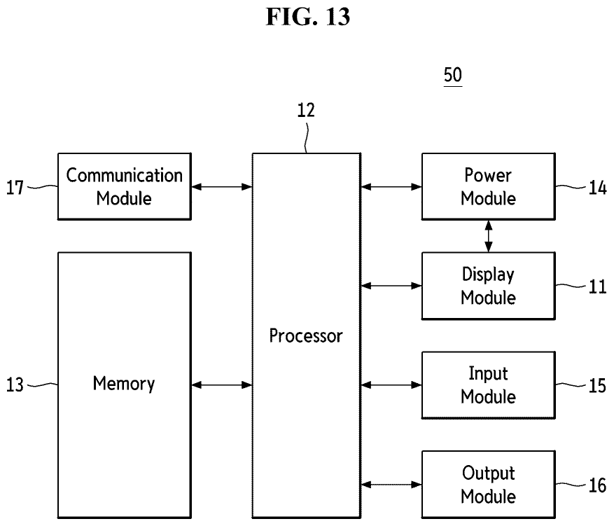

FIG. 13 is a block diagram of an electronic device according to some embodiments of the present disclosure. Referring to FIG. 13, the electronic device 50 according to some embodiments may include a display module 11 (e.g., a display device), a processor 12, a memory 13, and a power module 14. The electronic device 50 may further include an input module 15, a non-image output module 16 (e.g., an output module), and a communication module 17.

The electronic device 50 may output various information in the form of images through the display module 11. When the processor 12 executes an application stored in the memory 13, image information provided by the application may be provided to the user through the display module 11. The power module 14 may include a power supply module, such as a power adapter or a battery device, and a power conversion module that converts the power supplied by the power supply module to generate power for the operation of the electronic device 50. The input module 15 may provide input information to the processor 12 and/or the display module 11. The non-image output module 16 may receive information other than images transmitted from the processor 12, such as sound, haptics, and light, and provide the information to the 1 user. The communication module 17 is a module that is responsible for transmitting and receiving information between the electronic device 50 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device may include a display module 11, and the processor 12, memory 13, and power module 14 may be provided in the form of other devices within the electronic device 50 other than the display device.

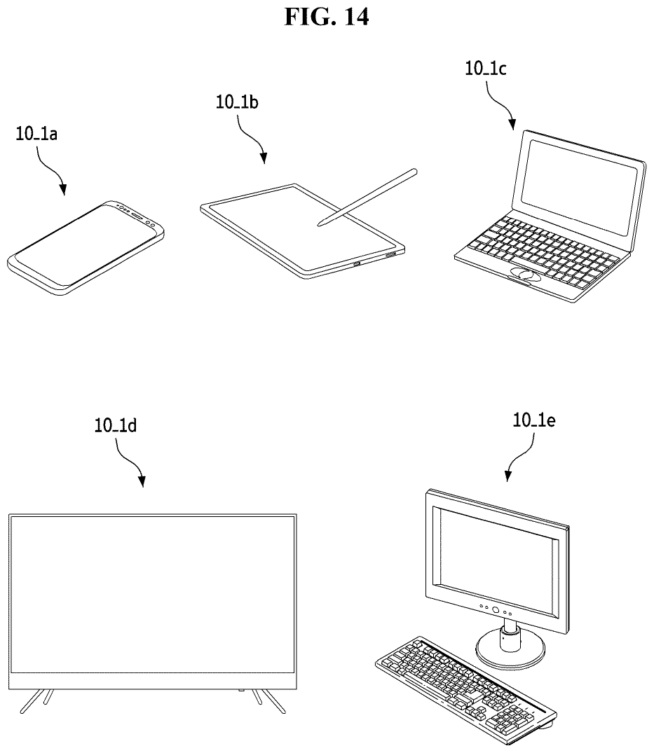

FIGS. 14, 15, and 16 are schematic diagrams of electronic devices according to some embodiments of the present disclosure. FIGS. 14 to 16 illustrate examples of various electronic devices to which the display device according to the embodiments may be applied.

FIG. 14 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module, such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they may include display modules and input modules similar to smartphones 10_1, and may additionally include communication modules in some cases.

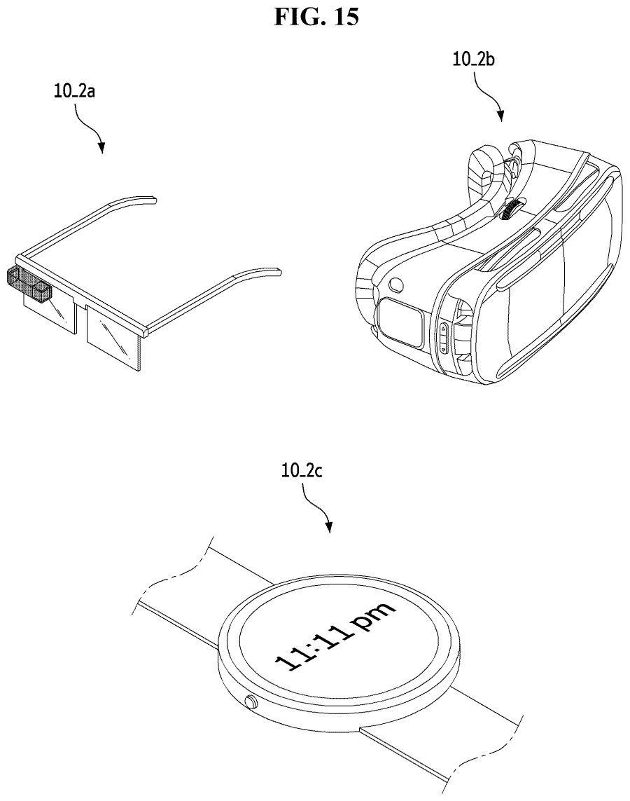

FIG. 15 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits light of a display image and a reflector that reflects the light emitted from the display screen and provides it to the user's eyes, thereby providing a virtual reality or augmented reality screen to the user.

The smart watch 10_2c may include a biometric sensor as an input device, and may provide biometric information recognized by the biometric sensor to the user through the display module.

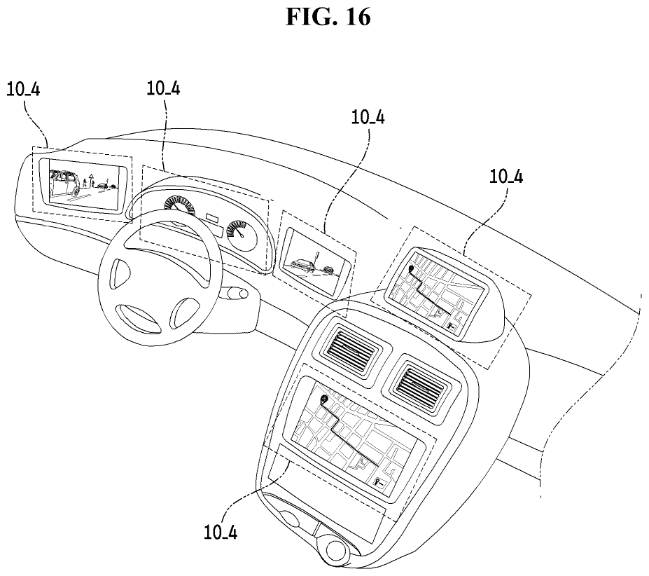

FIG. 16 illustrates a case where an electronic device including a display module is applied to a vehicle (e.g., a motor vehicle). For example, the electronic device 10_4 may be applied to a dashboard, center fascia, etc. of a vehicle, or may be applied to a CID (Center Information Display) placed on a dashboard of a vehicle, or a room mirror display replacing a side mirror.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a substrate comprising a display area and a non-display area;
a plurality of anode electrodes on the substrate;
a pixel defining film on the plurality of anode electrodes, and defining a plurality of emission areas;
a light emitting stack on the pixel defining film and the plurality of anode electrodes;
a cathode electrode on the light emitting stack;
a plurality of sub-optical layers on the cathode electrode; and
a lens on the plurality of sub-optical layers,
wherein a plurality of sub-pixels comprise a plurality of anode electrodes, a plurality of emission areas, a light emitting stack, a cathode electrode, a plurality of sub-optical layers, and a sub-optical layer shifted by a larger magnitude with an increase of its distance from a center of the display area, and
wherein a deviation of a shift distance between neighboring sub-pixels is about 0.001 μm to about 0.009 μm.

2. The display device of claim 1, wherein the deviation of the shift distance between the neighboring sub-pixels is about 0.001 μm.

3. The display device of claim 1, wherein the sub-optical layer comprises
a color filter; and
a sub-lens on the color filter and overlapping with the color filter.

4. The display device of claim 3, wherein the lens overlaps with a plurality of sub-lenses of the plurality of sub-pixels.

5. The display device of claim 3, wherein the sub-lens comprises a microlens.

6. The display device of claim 1, wherein the shift distance is a distance between a center of the emission area of the sub-pixel and a center of the sub-optical layer of the sub-pixel.

7. The display device of claim 1, wherein the neighboring sub-pixels are neighboring sub-pixels along an imaginary line connecting the center of the display area to an edge of the display area.

8. The display device of claim 1, wherein a rate of change in a chief ray angle varies gradually according to a distance from the center of the display area to the sub-pixel.

9. The display device of claim 8, wherein the rate of change of the chief ray angle gradually increases in proportion to the distance from the center of the display area to the sub-pixel.

10. The display device of claim 1, wherein the lens comprises a pancake lens.

11. An electronic device comprising:
a display device comprising:
a screen;
a substrate comprising a display area and a non-display area;
a plurality of anode electrodes on the substrate;
a pixel defining film on the plurality of anode electrodes, and defining a plurality of emission areas;
a light emitting stack on the pixel defining film and the plurality of anode electrodes;
a cathode electrode on the light emitting stack;
a plurality of sub-optical layers on the cathode electrode; and
a lens on the plurality of sub-optical layers,
wherein a plurality of sub-pixels comprise a plurality of anode electrodes, a plurality of emission areas, a light emitting stack, a cathode electrode, a plurality of sub-optical layers, and a sub-optical layer shifted by a larger magnitude with an increase of its distance from a center of the display area, and
wherein a deviation of a shift distance between neighboring sub-pixels is about 0.001 μm to about 0.009 μm.

12. The electronic device of claim 11, wherein the deviation of the shift distance between the neighboring sub-pixels is about 0.001 μm.

13. The electronic device of claim 11, wherein the sub-optical layer comprises:
a color filter; and
a sub-lens on the color filter and overlapping with the color filter.

14. The electronic device of claim 13, wherein the lens overlaps with a plurality of sub-lenses of the plurality of sub-pixels.

15. The electronic device of claim 13, wherein the sub-lens comprises a microlens.

16. The electronic device of claim 11, wherein the shift distance is a distance between a center of the emission area of the sub-pixel and a center of the sub-optical layer of the sub-pixel.

17. The electronic device of claim 11, wherein the neighboring sub-pixels are neighboring sub-pixels along an imaginary line connecting the center of the display area to an edge of the display area.

18. The electronic device of claim 11, wherein a rate of change in a chief ray angle varies gradually according to a distance from the center of the display area to the sub-pixel.

19. The electronic device of claim 18, wherein the rate of change of the chief ray angle gradually increases in proportion to the distance from the center of the display area to the sub-pixel.

20. The electronic device of claim 11, wherein the lens comprises a pancake lens.
